(19) United States
(12) Patent Application Publication
(10) Pub. No.: US 2025/0357150 A1
(43) Pub. Date: Nov. 20, 2025

(54) SUBSTRATE PROCESSING APPARATUS

(71) Applicant: SCREEN Holdings Co., Ltd., Kyoto (JP)

(72) Inventors: Zhida WANG, Kyoto (JP); Yuya AKANISHI, Kyoto (JP); Shuji MURAMOTO, Kyoto (JP); Hiroo KASAMATSU, Kyoto (JP); Daiki UEHARA, Kyoto (JP); Tomohiro MOTONO, Kyoto (JP); Koji OTAWA, Kyoto (JP); Samuel Alonso RODRIGUEZ, Kyoto (JP); Tomohiro FUJIWARA, Kyoto (JP); Kenta TAKATSU, Kyoto (JP)

(21) Appl. No.: 19/209,733

(22) Filed: May 15, 2025

(30) Foreign Application Priority Data
May 16, 2024 (JP) 2024-079867

(51) Int. Cl. H01L 21/67; F26B 3/00

(52) U.S. Cl. CPC H01L 21/67034; F26B 3/00

(57) ABSTRACT

A substrate processing apparatus according to the invention includes a processing chamber which has an internal space capable of storing the substrate, a supplier which supplies the processing fluid in the form of a liquid, a heater which heats the liquid processing fluid supplied from the fluid supplier to or above a critical temperature of the processing fluid and causing a transition into a supercritical state, a flow passage forming part which forms a flow passage of the processing fluid from the supplier to the processing chamber by way of the heater, a first filter which is disposed in the flow passage between the supplier and the heater and filters the liquid processing fluid and a second filter which is disposed in the flow passage between the heater and the processing chamber and filters the processing fluid in the supercritical state.

### CROSS REFERENCE TO RELATED APPLICATION

The disclosure of Japanese Patent Application No. 2024-079867 filed on May 16, 2024 including specification, drawings and claims is incorporated herein by reference in its entirety.

### BACKGROUND OF THE INVENTION

### 1. Field of the Invention

This invention relates to a technique for storing a substrate into a processing chamber and processing the substrate by a processing fluid in a supercritical state.

### 2. Description of the Related Art

A process of processing of various substrates such as a semiconductor substrate, a glass substrate for a display apparatus, and the like includes that of processing a surface of a substrate with various processing fluids. Processing using a liquid such as a chemical liquid, a rinse liquid, or the like as the processing fluid has been widely performed conventionally. Additionally, processing using a supercritical fluid has been put into practical use in recent years. In particular, in the processing of a substrate having a fine pattern formed on its surface, since the supercritical fluid having a surface tension lower than a liquid penetrates deep into gaps among the pattern, the processing can be performed efficiently. Further, it is possible to reduce a risk of occurrence of pattern collapse due to the surface tension during drying.

For example, in a substrate processing apparatus described in JP 2023-036123A (patent literature 1), a substrate is stored in a processing chamber while being placed on a flat plate-like supporting member. In the processing chamber, a processing fluid is introduced into each of a space above the substrate and a space below the supporting member, and laminar flows of the processing fluid are formed in these spaces and the substrate is processed. A filter for filtering the processing fluid to remove pollution-causing substances possibly contained in the processing fluid is disposed in each of a pipe for supplying the processing fluid to a side above the substrate and a pipe for supplying the processing fluid to a side below the substrate.

In a substrate processing technique for processing a substrate using a supercritical processing fluid, the processing fluid generally undergoes phase transitions among several states such as a gas phase, a liquid phase and a supercritical state in the processing process. Such phase transitions possibly occur in the pipes in which the processing fluid flows. On the other hand, in the filter provided in a piping system, a desired specification changes depending on whether the fluid to be processed is a gas or a liquid. That is, if the filter specification does not conform to the type of the flowing fluid and the purpose of arrangement, problems that desired filtering performance cannot be obtained. Further, an excessive load acts on the filter or the pipe and adversely affects these possibly occur.

Thus, which filter is arranged at which position of the piping system is important in obtaining a good filtering result, but this point is not mentioned in detail in the above conventional art. As just described, in an apparatus for performing a process using a supercritical processing fluid, careful consideration is necessary for the arrangement of filters in a piping system. However, it cannot be said that knowledge based on such a perspective has been sufficiently accumulated and it is desired to establish a technique for optimizing a filter arrangement.

### SUMMARY OF THE INVENTION

This invention was developed in view of the above problem and aims to propose a preferred arrangement of filters in a flow path of a processing fluid in a technique for processing a substrate by a supercritical processing fluid.

One aspect of this invention is directed to a substrate processing apparatus for processing a substrate by a processing fluid in a supercritical state, the substrate processing apparatus including a processing chamber which has an internal space capable of storing the substrate, a supplier which supplies the processing fluid in the form of a liquid, a heater which heats the liquid processing fluid supplied from the fluid supplier to or above a critical temperature of the processing fluid and causing a transition into a supercritical state, a flow passage forming part which forms a flow passage of the processing fluid from the supplier to the processing chamber by way of the heater, a first filter which is disposed in the flow passage between the supplier and the heater and filters the liquid processing fluid, and a second filter which is disposed in the flow passage between the heater and the processing chamber and filters the processing fluid in the supercritical state.

In the invention thus configured, the processing fluid supplied in the form of the liquid from the supplier is heated by the heater, brought into the supercritical state and introduced into the processing chamber. Thus, the processing fluid in the supercritical state is supplied to the processing chamber. The first filter is provided in the flow passage for the liquid from the supplier to the heater. The second filter is provided in the flow passage for the processing fluid in the supercritical state (hereinafter, may be merely referred to as a “supercritical fluid”) from the heater to the processing chamber.

As just described, the flow passage of the processing fluid can be clearly zoned across the heater with an upstream side of the heater as a zone in which the liquid flows and a downstream side of the heater as a zone in which the supercritical fluid flows. By arranging the filter in each zone, the filter specialized for the fluid to be processed can be applied. That is, a filter suitable for the processing of the liquid can be utilized as the first filter, and a filter suitable for the processing of the supercritical fluid can be utilized as the second filter.

As described above, according to the invention, the flow passage for feeding the processing fluid to the processing chamber is clearly zoned into the zone for handling the liquid and the zone for handing the supercritical fluid, and the filter is arranged in each zone. Thus, by selecting the filter corresponding to the fluid to be handled, the performance of the filter can be sufficiently exhibited and the substrate can be processed by the clean processing fluid having pollution-causing substances removed therefrom.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIG. 1 is a view showing a schematic configuration of a substrate processing system including one embodiment of a substrate processing apparatus.

FIGS. 2 and 3 are views each showing an exemplary configuration of the wet processing apparatus.

FIG. 4 is a side elevational view showing a configuration of the supercritical processing apparatus.

FIG. 5 is a diagram showing the details of the supply and discharge paths of the processing fluid.

FIG. 6 is a flow chart showing the process performed by the supercritical processing apparatus.

FIG. 7 shows graphs showing pressure changes in the processing chamber and the storage tank in this process.

FIG. 8 is a diagram showing a second embodiment of the substrate processing apparatus.

FIG. 9 is a diagram showing a third embodiment of the substrate processing apparatus.

FIG. 10 is a diagram showing a fourth embodiment of the substrate processing apparatus.

### DETAILED DESCRIPTION OF THE PREFERRED EMBODIMENTS

### First Embodiment

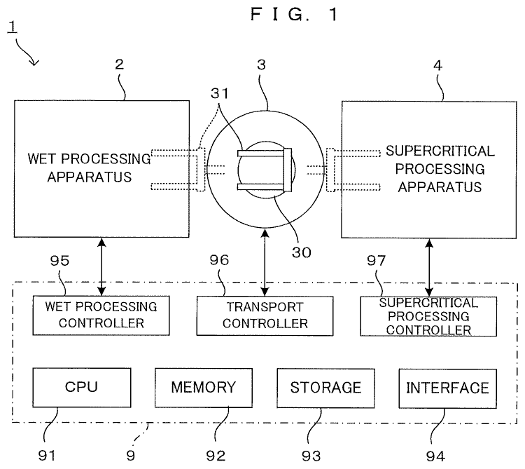

FIG. 1 is a view showing a schematic configuration of a substrate processing system including the first embodiment of a substrate processing apparatus in accordance with the present invention. This substrate processing system 1 is a processing system for wet-processing various substrates such as semiconductor wafers by supplying a processing fluid to an upper surfaces of the substrates and, thereafter, drying the substrates. The substrate processing system 1 has a suitable system configuration to carry out a substrate processing method according to the invention. The substrate processing system 1 includes a wet processing apparatus 2, a conveyance mechanism 3, a supercritical processing apparatus 4 and a control apparatus 9 as main components.

The wet processing apparatus 2 performs a predetermined wet processing by receiving a substrate to be processed. Contents of the processing are not particularly limited. Development process, cleaning process, and the like are included within the wet processing. After such processing, a puddle state in which a pattern formed surface of the substrate is covered by an organic solvent such as IPA is realized. The conveyance mechanism 3 carries out and conveys the substrate from the substrate processing apparatus 2 while maintaining the puddle state and carries the substrate into the supercritical processing apparatus 4. The supercritical processing apparatus 4 corresponds to a substrate processing apparatus of the invention and performs a dry processing (supercritical dry processing) using a processing fluid in a supercritical state for the carried-in substrate. These are installed in a clean room. Therefore, the conveyance mechanism 3 conveys the substrate in an air atmosphere and under an atmospheric pressure.

The control apparatus 9 realizes a predetermined process by controlling the operations of these apparatuses. For this purpose, the control apparatus 9 includes a CPU 91, a memory 92, a storage 93, an interface 94, and the like. The CPU 91 executes various control programs. The memory 92 temporarily stores processing data. The storage 93 stores the control programs to be executed by the CPU 91. The interface 94 performs information exchange with a user and an external apparatus. Operations of the apparatus to be described later are realized by the CPU 91 causing each component of the apparatus to perform a predetermined operation by executing the control program written in the storage 93 in advance.

The CPU 91 executes a predetermined control program, whereby functional blocks such as a wet processing controller 95 for controlling the operation of the wet processing apparatus 2, a conveyance controller 96 for controlling the operation of the conveyance mechanism 3 and a supercritical processing controller 97 for controlling the operation of the supercritical processing apparatus 4 are realized by software in the control apparatus 9. Note that each of these functional blocks may be at least partially configured by dedicated hardware.

Here, various substrates such as semiconductor wafers, glass substrates for photomask, glass substrates for liquid crystal display, glass substrates for plasma display, substrates for FED (Field Emission Display), optical disk substrates, magnetic disk substrates and magneto-optical disk substrates can be applied as the “substrate” in this embodiment. The substrate processing apparatus used in processing disk-shaped semiconductor wafers is mainly described as an example with reference to the drawings below. However, application to the processing of various substrates illustrated above is also possible. Further, various shapes of the substrate are also available.

Further, in the following description, a substrate having a pattern formed only on one principal surface is used as an example. Here, the principal surface formed with the pattern and the like is referred to as a “front surface” and a principal surface on an opposite side not formed with the pattern is referred to as a “back surface”. Further, the principal surface of the substrate facing downward is referred to as a “lower surface” and a principal surface of the substrate facing upward is referred to as an “upper surface”. Note that the upper surface is described as the front surface below.

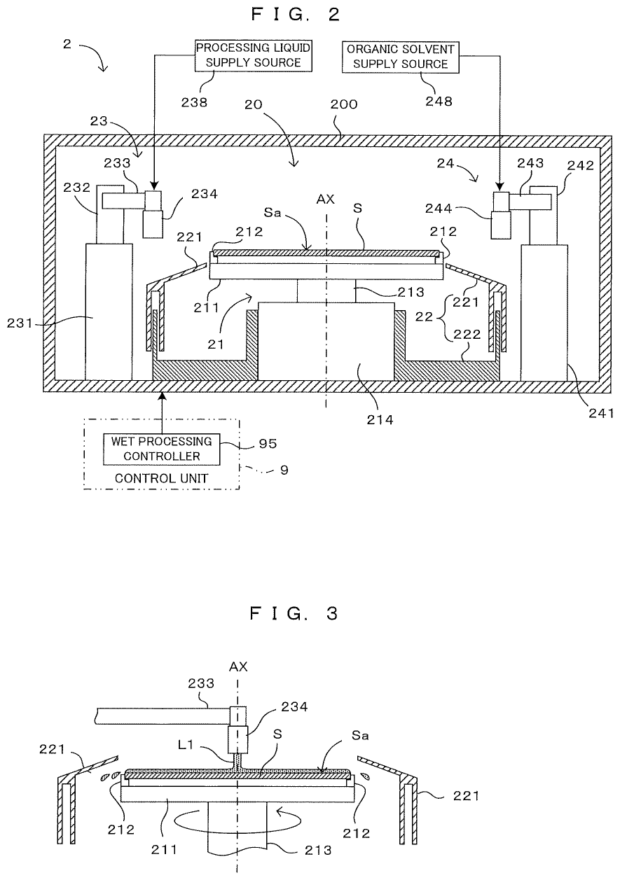

FIGS. 2 and 3 are views each showing an exemplary configuration of the wet processing apparatus. More specifically, FIG. 2 is a side elevational view showing an overall configuration of the wet processing apparatus 2. Further, FIG. 3 is a view showing an operation of the wet processing apparatus 2. This wet processing apparatus 2 is an apparatus for processing the substrate by supplying the processing fluid to the upper surface of the substrate. The operation of the wet processing apparatus 2 is controlled by the wet processing controller 95 of the control apparatus 9.

The wet processing apparatus 2 supplies a processing liquid to an upper surface (pattern forming surface) of a substrate S and performs a wet processing such as a surface processing for the substrate S cleaning processing, or the like. For this purpose, the wet processing apparatus 2 is provided with a substrate holder 21, a splash guard 22 and processing liquid suppliers 23, 24 inside the processing chamber 200. The operations of these are controlled by the wet processing controller 95 provided in the control apparatus 9. The substrate holder 21 includes a disk-like spin chuck 211 having a diameter nearly equal to that of the substrate S, and a plurality of chuck pins 212 are provided on a peripheral edge part of the substrate S. The chuck pins 212 support the substrate S by contacting a peripheral part of the substrate S, thereby the spin chuck 211 can support the substrate S in the horizontal posture in a state that the substrate S is apart from an upper surface thereof.

The spin chuck 211 is so supported that the upper surface thereof is horizontal by a rotary support shaft 213 extending downward from a central part of the lower surface of the spin chuck 211. The rotary support shaft 213 is rotatably supported by a rotating mechanism 214 mounted in a bottom part of the processing chamber 200. The rotating mechanism 214 includes an unillustrated built-in rotary motor. The rotary motor rotates in response to a control command from the control apparatus 9, whereby the spin chuck 211 directly coupled to the rotary support shaft 213 rotates about the axis AX of rotation indicated by a dashed-dotted line. In FIG. 2, an up-down direction is a vertical direction. In this way, the substrate S is rotated about the axis AX of rotation while being held in a horizontal position.

The splash guard 22 is provided to laterally surround the substrate holder 21. The splash guard 22 includes a substantially tubular cup 221 provided to cover the peripheral edge part of the spin chuck 211 and a liquid receiver 222 provided below an outer peripheral part of the cup 221. The cup 211 is raised and lowered in response to a control command from the control apparatus 9. The cup 221 is raised and lowered between a lower position shown in FIG. 2 and an upper position shown in FIG. 3. At the lower position, an upper end part of the cup 221 is lowered to below the peripheral edge part of the substrate S held by the spin chuck 211. At the upper position, the upper end part of the cup 221 is located above the peripheral edge part of the substrate S.

As shown in FIG. 2, when the cup 221 is at the lower position, the substrate S held by the spin chuck 211 is exposed to the outside of the cup 221. Thus, the cup 221 is prevented from becoming an obstacle when, for example, the substrate S is carried to and from the spin chuck 211.

Further, as shown in FIG. 3, the cup 221 surrounds the peripheral edge part of the substrate S held by the spin chuck 211 when being at the upper position. In this way, the processing liquid shaken off from the peripheral edge part of the substrate S during liquid supply to be described later is prevented from scattering in the chamber 200, and the processing liquid can be reliably collected. That is, by the rotation of the substrate S, droplets of the processing liquid shaken off from the peripheral edge part of the substrate S adhere to the inner wall of the cup 221, flow down and are finally gathered and collected by the liquid receiver 222 arranged below the cup 221. To individually collect a plurality of processing liquids, cups may be concentrically provided at a plurality of levels.

The processing liquid supplier 23 is structured such that a nozzle 234 is attached to the tip of an arm 233 horizontally extending from a rotary support shaft 232 provided rotatably with respect to a base 231 fixed in the processing chamber 200. The rotary support shaft 232 rotates in response to a control command from the control apparatus 9, whereby the arm 233 pivots. In this way, the nozzle 234 on the tip of the arm 233 moves between a retreated position shown in FIG. 2A retreated laterally from above the substrate S and a processing position shown in FIG. 2B above the substrate S.

The nozzle 234 is connected to a processing liquid supply source 238. If an appropriate processing liquid is sent out from the processing liquid supply source 238, the processing liquid is discharged toward the substrate S from the nozzle 234. As shown in FIG. 3, by supplying the processing liquid L1 from the nozzle 234 positioned above a center of rotation of the substrate S while rotating the substrate S by the rotation of the spin chuck 211 at a relatively low speed, an upper surface Sa of the substrate S is processed by the processing liquid L1. Liquids having various functions such as developing liquids, etching liquids, cleaning liquids, rinsing liquids and the like can be used as the processing liquid L1, and a composition of the processing liquid is arbitrary. Further, the processing may be performed with a plurality of types of processing liquids combined.

Another processing liquid supplier 24 also has a configuration corresponding to the first processing liquid supplier 23 described above. That is, the second processing liquid supplier 24 includes a base 241, a rotary support shaft 242, an arm 243, a nozzle 244 and the like. The configurations of these are the same as those of the corresponding components of the first processing liquid supplier 23. The rotary support shaft 242 rotates in response to a control command from the control apparatus 9, whereby the arm 243 pivots. The nozzle 244 on the tip of the arm 243 supplies a processing liquid to the upper surface Sa of the substrate S.

In this embodiment, the second processing liquid supplier 24 is used for the purpose of forming a liquid film for preventing dryness on the substrate S after the wet processing. That is, the substrate S after the wet processing is conveyed to the supercritical processing apparatus 4 and receives a supercritical drying processing. At this time, to prevent the surface of the substrate S from being exposed and oxidized during conveyance and prevent the collapse of the fine pattern formed on the surface, the substrate S is conveyed with the surface thereof covered with a puddle-like liquid film.

A substance having a lower surface tension than water, which is a main component of a processing liquid used in a cleaning processing, e.g. an organic solvent such as isopropyl alcohol (IPA) or acetone, is used as the liquid for constituting the liquid film.

Although two processing liquid suppliers are provided in the wet processing apparatus 2 here, the number, structures and functions of the processing liquid suppliers are not limited to these. For example, only one processing liquid supplier may be provided or three or more processing liquid suppliers may be provided. Further, one processing liquid supplier may include a plurality of nozzles. For example, a plurality of nozzles may be provided on the tip of one arm. Further, the processing liquid is not only discharged with the nozzle positioned at the predetermined position as described above, but also may be, for example, discharged while the nozzle is scanned and moved along the upper surface Sa of the substrate S.

Referring back to FIG. 1, the conveyance mechanism 3 is provided with a conveyor robot 30 provided with a hand 31 on the tip of a telescopic/rotatable arm. The hand 31 can support the substrate by partially contacting the lower surface of the substrate and, as shown by dotted lines in FIG. 1, is movable toward and away from both the wet processing apparatus 2 and the supercritical processing apparatus 4. In this way, the substrate can be carried in and out from each of the wet processing apparatus 2 and the supercritical processing apparatus 4. The operation of the conveyor robot 30 is controlled by the conveyance controller 96 of the control apparatus 9. Many techniques are known as conveyor robots of this type, and one of those can be appropriately selected and used also in this embodiment. Therefore, detailed description is omitted.

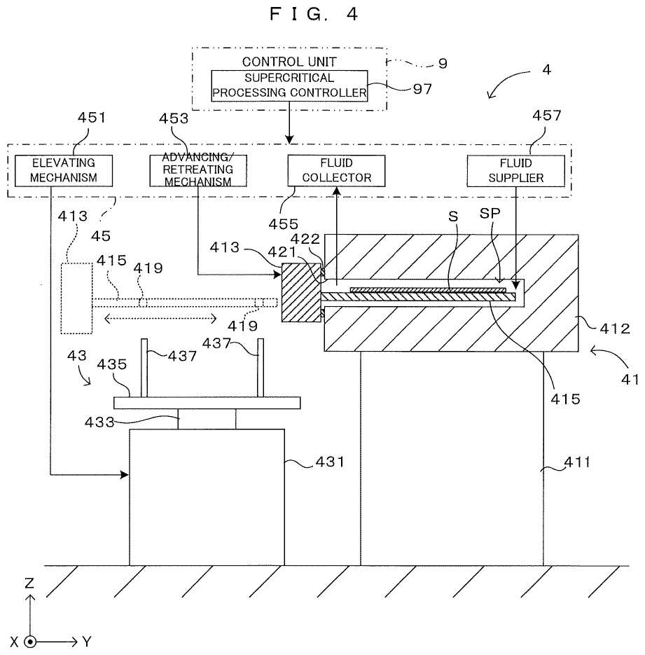

FIG. 4 is a side elevational view showing a configuration of the supercritical processing apparatus. The supercritical processing apparatus 4 corresponds to an embodiment of the substrate processing apparatus according to the invention and is an apparatus for applying a drying processing using a processing fluid in a supercritical state to the substrate S after the wet processing. More specifically, the supercritical processing apparatus 4 finally brings the substrate S to a dry state by discharging the processing fluid after receiving the substrate S after the wet processing and replacing the liquid remaining on the substrate S by the processing fluid in the supercritical state.

The supercritical processing apparatus 4 is provided with a processing unit 40, a transfer unit 43 and a supply unit 45. The processing unit 41 serves as an executor of the supercritical drying processing. The transfer unit 43 receives the substrate S after the wet processing conveyed by the conveyance mechanism 3, carries the substrate S into the processing unit 40 and transfers the processed substrate S from the processing unit 40 to an external conveyor device. The supply unit 45 supplies chemical substances, power, energy and the like necessary for the processing to the processing unit 40 and the transfer unit 43. These operations are controlled by the control apparatus 9, particularly by the supercritical processing controller 97.

The processing unit 41 is structured such that a processing chamber 412 is mounted on a pedestal 411. The processing chamber 412 is configured by a combination of several metal blocks and the inside thereof is hollow and constitutes a processing space SP. The substrate S to be processed is carried into the processing space SP and processed. A slit-like aperture 421 elongated in the X direction is formed in a side surface on the (−Y) side of the processing chamber 412. The processing space SP and an outside space communicate via the aperture 421. A cross-sectional shape of the processing space SP is substantially the same as an opening shape of the aperture 421. That is, the processing space SP is a hollow having a cross-sectional shape long in the X direction and short in the Z direction and extending in the Y direction.

A lid member 413 is provided to close the aperture 421 on a side surface on the (−Y) side of the processing chamber 412. The lid member 413 closes the aperture 421 of the processing chamber 412, whereby an airtight processing container is configured. In this way, the substrate S can be processed under a high pressure in the processing space SP inside. A support tray 415 in the form of a flat plate is mounted in a horizontal position on a side surface on the (+Y) side of the lid member 413. The upper surface of the support tray 415 serves as a support surface, on which the substrate S can be placed. The lid member 413 is supported horizontally movably in the Y direction by an unillustrated supporting mechanism.

The lid member 413 is movable toward and away from the processing chamber 412 by an advancing/retreating mechanism 453 provided in the supply unit 45. Specifically, the advancing/retreating mechanism 453 includes a linear motion mechanism such as a linear motor, a linear motion guide, a ball screw mechanism, a solenoid or an air cylinder. Such a linear motion mechanism moves the lid member 413 in the Y direction. The advancing/retreating mechanism 453 operates in response to a control command from the control apparatus 9.

The lid member 413 is separated from the processing chamber 412 by moving in the (−Y) direction. If the support tray 415 is pulled out from the processing space SP to outside via the aperture 421 as indicated by a dotted line, the support tray 415 becomes accessible. That is, the substrate S can be placed on the support tray 415 and the substrate S placed on the support tray 415 can be taken out. On the other hand, by a movement of the lid member 413 in the (+Y) direction, the support tray 415 is accommodated into the processing space SP. If the substrate S is placed on the support tray 415, the substrate S is carried into the processing space SP together with the support tray 415.

The processing space SP is closed by the lid member 413 moving in the (+Y) direction and closing the aperture 421. A sealing member 422 is provided between the side surface on the (+Y) side of the lid member 413 and the side surface on the (−Y) side of the processing chamber 412 to hold the processing space SP airtight. The sealing member 422 is, for example, made of rubber. Further, the lid member 413 is fixed to the processing chamber 412 by an unillustrated lock mechanism. As just described, in this embodiment, the lid member 413 is switched between a closing state (solid line) for sealing the processing space SP by closing the aperture 421 and a separated state (dotted line) where the lid member 413 is largely separated from the aperture 421 to enable the substrate S to be taken in and out.

With the airtight state of the processing space SP ensured, the substrate S is processed in the processing space SP. In this embodiment, a fluid supplier 457 provided in the supply unit 45 sends out a processing fluid and further brings the processing fluid into a supercritical state by pressurizing the processing fluid in the processing chamber 412. The processing fluid is supplied in a gas or liquid state to the processing unit 40. A substance usable in the supercritical processing, e.g. carbon dioxide, can be used as the processing fluid. Carbon dioxide is a chemical substance suitable for the supercritical drying processing in having a property of entering the supercritical state at relatively low temperature and low pressure and dissolving into an organic solvent often used in substrate processing well. At a critical point at which carbon dioxide enters the supercritical state, an atmospheric pressure (critical pressure) is 7.38 MPa and a temperature (critical temperature) is 31.1° C.

If the processing fluid is filled into the processing space SP and the inside of the processing space SP reaches suitable temperature and pressure, the processing space SP is filled with the processing fluid in the supercritical state. In this way, the substrate S is processed by the processing fluid in the supercritical state in the processing chamber 412. The supply unit 45 is provided with a fluid collector 455, and the fluid after the processing is collected by the fluid collector 455. The fluid supplier 457 and the fluid collector 455 are controlled by the supercritical processing controller 97.

The processing space SP has a shape and a volume capable of receiving the support tray 415 and the substrate S supported by the support tray 415. That is, the processing space SP has a substantially rectangular cross-sectional shape wider than a width of the support tray 415 in a horizontal direction and having a height larger than that of the support tray 415 and substrate S combined in the vertical direction. Further, the processing space SP has a depth capable of receiving the support tray 415. As just described, the processing space SP has a shape and a volume enough to receive the support tray 415 and the substrate S. However, gaps between the support tray 415 and the substrate S and the inner wall surface of the processing space SP are tiny. Therefore, the amount of the processing fluid necessary to fill the processing space SP can be relatively small.

The fluid supplier 457 supplies the processing fluid to the processing space SP on a side further in the (+Y) direction than the end part on the (+Y) side of the substrate S. On the other hand, the fluid collector 55 discharges the processing fluid flowing in a space above the substrate S and a space below the support tray 415, out of the processing space SP, on a side further in the (−Y) direction than the end part on the (−Y) side of the substrate S. In this way, laminar flows of the processing fluid from the (+Y) side toward the (−Y) side are respectively formed above the substrate S and below the support tray 415 in the processing space SP.

The supercritical processing controller 97 of the control apparatus 9 specifies the pressure and temperature in the processing space SP based on a detection result of an unillustrated detector and controls the fluid supplier 457 and the fluid collector 455 based on that result. In this way, the supply of the processing fluid into the processing space SP and the discharge of the processing fluid from the processing space SP are properly managed. The pressure and temperature in the processing space SP are adjusted according to a processing recipe determined in advance.

The transfer unit 43 is in charge of the transfer of the substrate S between the conveyance mechanism 3 and the support tray 415. For this purpose, the transfer unit 43 is provided with a body 431, an elevating member 433, a base member 435 and a plurality of lift pins 437. The elevating member 433 is a columnar member extending in the Z direction, and supported movably in the Z direction with respect to the body 431 by an unillustrated supporting mechanism. The base member 435 having a substantially horizontal upper surface is mounted atop the elevating member 433. The plurality of lift pins 437 stand up from the upper surface of the base member 435. The respective lift pins 437 support the substrate S in a horizontal position from below by the contact of upper end parts thereof with the lower surface of the substrate S. Three or more lift pins 437 having the upper end parts at the same height are desirably provided to stably support the substrate S in the horizontal position.

The elevating member 433 is made movable up and down by an elevating mechanism 451 provided in the supply unit 45. Specifically, the elevating mechanism 451 includes a linear motion mechanism such as a linear motor, a linear motion guide, a ball screw mechanism, a solenoid or an air cylinder. Such a linear motion mechanism moves the elevating member 433 in the Z direction. The elevating mechanism 451 operates in response to a control command from the control apparatus 9.

The base member 435 is moved up and down by upward and downward movements of the elevating member 433. The plurality of lift pins 437 move up and down integrally with the base member 435. In this way, the transfer of the substrate S is realized between the transfer unit 43 and the support tray 415. More specifically, as shown by dotted lines in FIG. 4, the substrate S is transferred with the support tray 415 pulled out to the outside of the chamber. For this purpose, the support tray 415 is provided with through holes 419, through which the lift pins 437 are inserted. If the base member 435 is raised, the upper ends of the lift pins 437 reach above the upper surface of the support tray 415 through the through holes 419. In this state, the substrate S conveyed by the conveyor robot 30 is transferred from the hand 31 of the conveyor robot 30 to the lift pins 437. By lowering the lift pins 437, the substrate S is transferred from the lift pins 437 to the support tray 415. The substrate S can be carried out by a procedure opposite to the above one.

Next, a supply path of the processing fluid to the processing chamber 412 and a discharge path of the processing fluid from the processing chamber 412 are more specifically described. In the above concise description, the processing fluid is supplied from the fluid supplier 457 to the processing chamber 412 and the processing fluid is collected from the processing chamber 412 to the fluid collector 455. In an actual apparatus, the fluid supplier 457 and the fluid collector 455 have the following configurations.

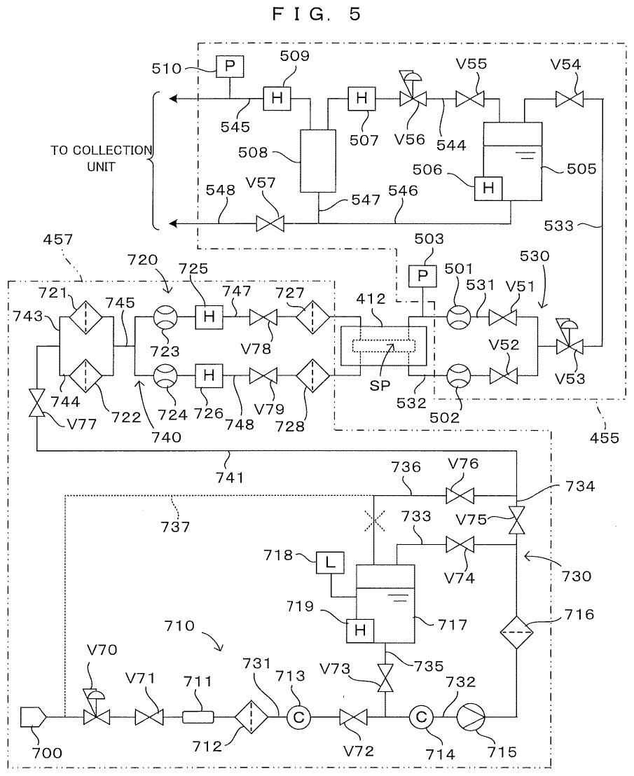

FIG. 5 is a diagram showing the details of the supply and discharge paths of the processing fluid. Note that, in FIG. 5, the orientation of the processing chamber 412 is opposite to that in FIG. 4 for the sake of graphical representation. That is, in FIG. 4, the processing fluid is introduced into the processing chamber 412 from a right side and discharged to a left side. On the other hand, in FIG. 5, the processing fluid is conversely introduced into the processing chamber 412 from a left side and discharged to a right side. That is, a surface of the processing chamber 412 shown in FIG. 5 is opposite to a surface of the processing chamber 412 shown in FIG. 4.

First, the detailed structure of the fluid supplier 457 is described. The fluid supplier 457 is provided with a fluid supply source 700, a refining unit 710, a supply unit 720 and pipe groups 730, 740 connecting these as main components. These operate in response to a control command from the supercritical processing controller 97.

The fluid supply source 700 outputs a substance (carbon dioxide in this embodiment) acting as the processing fluid in the supercritical process if necessary. The fluid supply source 700 may be provided as a part of this substrate processing system 1 and can be configured by a container such as a cylinder for storing this substance. Further, the fluid supply source 700 may be an external supply source provided separately from the substrate processing system 1.

A pipe 731, which is a part of the pipe group 730, is connected to the fluid supply source 700. The processing fluid fed from the fluid supply source 700 is fed rightward in FIG. 5 through the pipe 731. Valves V70, V71, a purifier 711, a filter 712, a condenser 713 and a valve V72 are disposed in this order along a flowing direction of the processing fluid. The valve V70 is, for example, a pressure regulating valve having a function of regulating a pressure of the processing fluid fed through the pipe 731. The other valves V71, V72 are on-off valves for switching the flow of the fluid on and off.

The valve V70 allows the processing fluid having a pressure designated by a control command from the supercritical processing controller 97 to flow in the pipe 731. The purifier 711 and the filter 712 remove impurities contained in the processing fluid to improve purity. The condenser 713 condenses the processing fluid fed as a gas from the fluid supply source 700. If the valves V71, V72 are opened, the processing fluid is output from the pipe 731.

The pipe 731 joins a pipe 735 connected to a later-described storage tank 717 on an output side of the valve V72. A condenser 714, a pressure pump 715 and a filter 716 are provided in a pipe 732 after joining. The condenser 714 is provided to more reliably maintain the processing fluid in a liquid-phase state. The pressure pump 715 pressurizes and feeds the processing fluid in a liquid state. The filter 716 removes impurities from the processing fluid.

The pipe 732 is branched into two pipes 733, 734 on an output side of the filter 716. The pipe 733 is connected to an upper part of the storage tank 717 and a valve V74, which is an on-off valve, is disposed at a halfway position. Further, a valve V75, which is an on-off valve, is disposed in the pipe 734.

The storage tank 717 is a high-pressure container having a function of storing the pressurized processing fluid in the liquid state. A level sensor 718 is provided in the storage tank 717 to control a liquid surface height. Accordingly, an internal space of the storage tank 717 is not in a liquid-tight state, and the vaporized processing fluid is stored in a state pressurized to a pressure nearly equal to that of a liquid is stored in a space above the liquid surface. Further, a heater 719 is attached to the storage tank 717, and the heater 719 can heat the processing fluid in the tank in response to a control command from the supercritical processing controller 97.

The pipe 735 is connected to a lower part of the storage tank 717 and joins the pipe 731 and is connected to the pipe 732. If a valve V73, which is an on-off valve, disposed in the pipe 735 is opened, the liquid of the processing fluid in the storage tank 717 flows into the pipe 732 via the pipe 735. If the valve V74 in the pipe 733 is further opened, a return flow passage returning to the storage tank 717 from the storage tank 717 by way of the pipes 735, 732 and 733 is formed. If the pressure pump 715 pressurizes the processing fluid while circulating the processing fluid in this return flow passage, the pressure of the processing fluid can be increased stepwise. Finally, the processing fluid increased to a pressure designated by a control command from the supercritical processing controller 97 is stored in the storage tank 717.

A pipe 736 for output is connected to an upper part of the storage tank 717 and joins the pipe 734 via a valve V76, which is an on-off valve. The gaseous processing fluid filling an upper part of the internal space of the storage tank 717 is output from the pipe 736. The gaseous processing fluid when the valve V76 is opened and the liquid processing fluid when the valve V75 is opened selectively flow into a pipe 741 after the pipes 734, 736 join.

As just described, the refining unit 710 of the fluid supplier 457 has a function of selectively outputting the processing fluids in the phases necessary for a process later, specifically in the gas phase and the liquid phase, after removing impurities from the processing fluid supplied from the fluid supply source 700.

The pipe 741 is a part of the pipe group 740 constituting an introduction flow passage for introducing the processing fluid into the processing chamber 412 from the refining unit 710. The pipe 741 is branched into two pipes 743, 744, and filters 721, 722 are respectively provided in these pipes. These pipes join once to become a pipe 745, which is further branched into two pipes 747, 748.

A flow meter 723, a heater 725, a valve V78, which is an on-off valve, and a filter 727 are disposed in this order along a flowing direction (rightward in FIG. 5) of the processing fluid in a pipe 747, and the pipe 747 is finally connected to the processing chamber 412. More specifically, the pipe 747 communicates with an internal space SP above a support tray 415 (FIG. 4) for supporting the substrate S. On the other hand, a flow meter 724, a heater 726, a valve V79, which is an on-off valve, and a filter 728 are disposed in this order along a flowing direction of the processing fluid in the pipe 748. The pipe 748 communicates with the internal space SP of the processing chamber 412 below the support tray 415 (FIG. 4) for supporting the substrate S. In this way, the processing fluid is supplied to the respective spaces above and below the substrate S placed on the support tray 415 in the internal space SP.

The flow meters 723, 724 measure a flow rate of the processing fluid at the respective positions, and transmit measurement results to the supercritical processing controller 97. The heaters 725, 726 heat the processing fluid to a predetermined temperature in response to a control command from the supercritical processing controller 97. The filters 727, 728 finally remove impurities from the processing fluid to be introduced into the processing chamber 412.

As just described, the fluid supplier 457 can supply the processing fluid purified and further having the temperature and pressure regulated to predetermined target values to the processing chamber 412. A supply sequence of the processing fluid from the fluid supplier 457 to the processing chamber 412 is described in detail later.

The processing fluid to be supplied to the processing chamber 412 is fed from the storage tank 717 and the processing fluid pressurized by the pressure pump 715 is stored in the storage tank 717. Thus, the pressure of the processing fluid fed from the fluid supply source 700 may be lower than a pressure necessary for the process. Note that if the fluid supply source 700 can stably feed the processing fluid having the pressure suitable for the process, the processing fluid in the gas phase may be directly supplied from the fluid supply source 700 via a pipe 737 without being taken out from the storage tank 717 as shown by a dotted line in FIG. 5. Further, the pressure-regulated processing fluid may be supplied from an output side of the valve V70.

As described above, in the fluid supplier 457 of this embodiment, the refining unit 710 has a function of storing the processing fluid output in the form of a gas from the fluid supply source 700 after purifying and liquefying the processing fluid. The processing fluid output in the form of the liquid from the refining unit 710 is brought into the supercritical state by being heated in the supply unit 720, and introduced into the processing chamber 412.

Several filters are arranged in the flow passage of such a processing fluid. Specifically, the filter 712 is disposed in the pipe 731 in which the processing fluid in the form of the gas flows. The processing fluid at this time is constantly the gas and the pressure thereof is regulated by the valve V70, which is a pressure regulating valve. Therefore, a filter unit suitable to handle the gas having this pressure can be applied as the filter 712. For example, it is possible to use a filter unit structured to store a filter element in a housing made of resin.

On the other hand, out of the filters provided in the supply unit 720, those on an upstream side, i.e. the filters 721, 722, are disposed in the pipe 741 in which the processing fluid flows in the form of the liquid having a high pressure. The processing fluid flowing in the pipe 741 is constantly the liquid, and the pressure thereof is stable. Accordingly, it is possible to use a filter unit suitable for the processing of such a fluid, e.g. a filter unit structured to store a filter element in a housing made of metal. The filter units used as two filters 721, 722 have the same structure here.

The filters 721, 722 are connected in parallel in the flow passage. That is, the filter units having the same structure are arranged in parallel in the flow passage of the liquid. Main reasons for this are as follows. The first reason is to ensure a sufficiently large flow quantity of the processing fluid in this part. The second reason is to suppress temperature drops of the filter units.

The first reason is described in more detail. The flow passage of the processing fluid is branched into two on a downstream side of the filters 721, 722, and the processing fluid is fed to each of the space above the substrate S and the space below the support tray 415, out of the processing space SP. Since the processing fluid to be supplied to both of these is fed in the pipe 741, a filter for receiving this is required to have a large capacity.

In this sense, a filter unit having a large capacity may be singly used. However, filter units excellent in particle removal performance often have a small size, and required filtering performance cannot be obtained only by using a filter unit merely having a large capacity. Accordingly, high filtering performance and large capacity can be combined by connecting small-size filter units excellent in performance in parallel.

Three or more filter units may be connected in parallel. However, it is also thought to rather increase pollution causes by increasing components such as pipes and joints connecting those filter units. Thus, it is preferable to determine the number of the filter units to be disposed in view of a balance between performance and capacity.

Next, the second reason is described in more detail. Since the filter at this position is for handling the liquid and the fluid in the liquid phase has a higher viscosity as compared to those in other states, a pressure loss in the filter is relatively large. Thus, a temperature drops due to a sudden pressure drop of the processing fluid passing through the filter, whereby the filter unit is cooled. In an experiment by the inventors of this application, a phenomenon in which dew condensation occurs in the housing is actually confirmed. Particularly in a filter unit including a housing made of metal, corrosion and rusting due to condensation may occur.

A more serious problem is that the processing fluid itself is cooled and partially solidified in the filter unit to cause the clogging of the filter. Since a flow rate of the processing fluid is reduced to further increase a pressure loss in this way, the clogging once occurred is hardly solved. Further, a variation of the flow rate of the processing fluid also largely affects the process in the processing chamber 412.

By connecting the filter units in parallel and distributing the flow of the processing fluid, the pressure loss in each filter unit is reduced and the temperature drops more gently. In this way, it is possible to largely reduce the occurrence risk of the clogging due to condensation on the housings and the solidification of the processing fluid in the filter units.

Since the filters 727, 728 arranged immediately before the processing chamber 412 in the flow passage finally determine the cleanliness of the processing fluid to be introduced into the processing space SP, high particle removal performance is required. Accordingly, filter units each using a housing made of metal hardly becoming a new pollution source are suitable. Also in this case, a problem of a temperature drop possibly occurs, but it does not cause a big problem unlike the previous filters 721, 722. The reason for that is as follows. First, the pressure loss is small since the fluid handled is a supercritical fluid having a low viscosity. Further, the temperature is less likely to drop to such a low temperature that condensation and the solidification of the processing fluid occur since the processing fluid is heated by the heaters 725, 726.

Further, the processing fluid is distributed in two flow passages in advance. Therefore, it is not always necessary to connect the filter units in parallel in each flow passage. Further, in the filters 727, 728, high-performance and small-size filter units may be used by being connected in parallel with more importance placed on performance.

A filter unit assuming the processing of the supercritical fluid is not generally easily available. However, the supercritical fluid may be regarded as a liquid having a very low viscosity and a filter designed for such a liquid can be used. For example, the filters 727, 728 can be constituted by filter units having the same structures as the filters 721, 722. By doing so, a cost advantage is obtained by commonly using filter bodies and exchange components.

The processing fluid passes in the form of the liquid through the filter 716 provided downstream of the pressure pump 715. Since this processing fluid has a relatively large flow quantity and the pressure thereof also largely changes, it is desirable to use a filter unit suitable for such a use. For example, a filter unit structured to store a filter element in a housing made of metal can be used. Note that a plurality of filter units may be also connected in parallel here. However, since high particle removal performance is not necessarily required for the filter at this position, a filter unit having a large capacity, but somewhat poor in performance can be singly used.

As just described, several filters are arranged in the flow passage of the processing fluid, but each of them is appropriately selected according to the state of the fluid handled and required performance.

Next, the detailed structure of the fluid collector 455 is described. The fluid collector 455 is provided with a high-pressure exhaust tank 505, a low-pressure exhaust tank 508, and a pipe group 530 connecting these as main components. These operate in response to a control command from the supercritical processing controller 97.

A pipe 531 constituting a part of the pipe group 530 is connected to an upper part of the processing chamber 412. On the other hand, a pipe 532 is connected to a lower part of the processing chamber 412. These pipes 531, 532 respectively discharge the processing fluid flowing above and below the support tray 415 in the internal space SP to outside from the processing chamber 412. A pressure meter 503 is provided in the pipe 531.

A flow meter 501 and a valve V51, which is an on-off valve, are disposed in this order along a flowing direction of the processing fluid in the pipe 531. On the other hand, a flow meter 502 and a valve V52, which is an on-off valve, are disposed in this order along a flowing direction of the processing fluid in the pipe 532. The pipes 531, 532 join on an output side of the valves V51, V52. A valve V53, which is a pressure regulating valve, and a valve V54, which is an on-off valve, are disposed in a pipe 533 after joining.

The pipe 533 is connected to the high-pressure exhaust tank 505, and the processing fluid discharged from the processing chamber 412 is stored in the high-pressure exhaust tank 505 via the pipe 533. A heater 506 is provided in the high-pressure exhaust tank 505 to properly keep the temperature of the pressure stored inside.

A pipe 544 is connected to an upper part of the high-pressure exhaust tank 505, a valve V55, which is an on-off valve, a valve 56, which is a pressure regulating valve, and a heater 507 are disposed in the pipe 544, and the pipe 544 is finally connected to the low-pressure exhaust tank 508. Accordingly, the processing fluid as a gas having the pressure and temperature appropriately regulated flows into the low-pressure exhaust tank 508. The processing fluid in the low-pressure exhaust tank 508 is finally collected by an unillustrated external collection device via a pipe 545. A heater 509 for adjusting a temperature of the gas to be discharged to outside and a pressure meter 510 for detecting the pressure of the gas are provided in the pipe 545.

Further, a pipe 546 is connected to a lower part of the high-pressure exhaust tank 505, whereas a pipe 547 is connected to a lower part of the low-pressure exhaust tank 508. These pipes are joined to become a pipe 548, and a valve V57, which is an on-off valve, is connected to the pipe 548. If the valve V57 is opened, the liquid processing fluid stored in the high-pressure exhaust tank 505 and the low-pressure exhaust tank 508 is discharged to the external collection device.

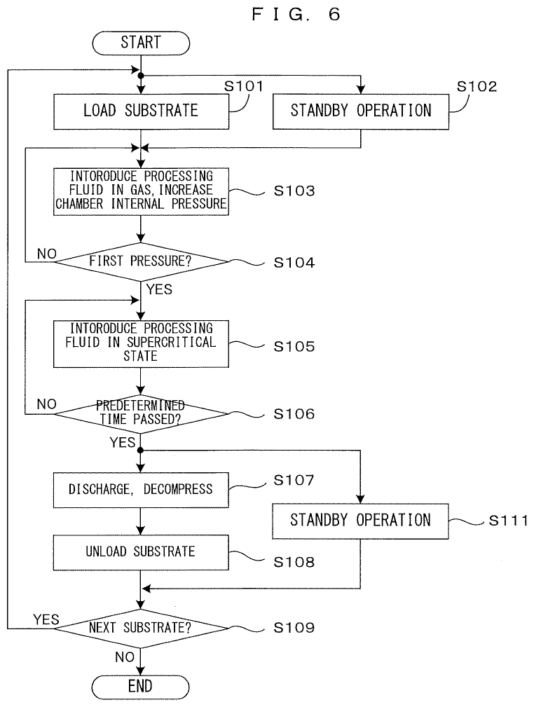

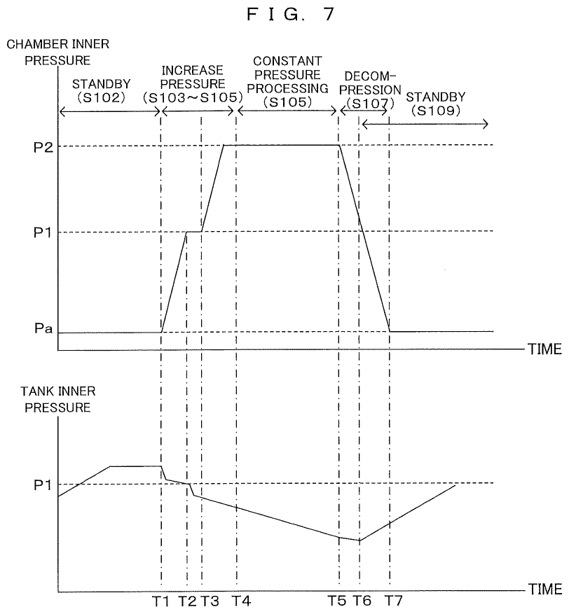

The operation of the supercritical processing apparatus 4 configured as described above is described with reference to FIGS. 6 and 7. The supercritical processing apparatus 4 performs a process of bringing the substrate S after the wet processing into a dry state using the processing fluid in the supercritical state, i.e. a supercritical drying process. This process is realized by the CPU 91 of the control apparatus 9 controlling each component of the apparatus by implementing the control program prepared in advance.

FIG. 6 is a flow chart showing the process performed by the supercritical processing apparatus. FIG. 7 shows graphs showing pressure changes in the processing chamber and the storage tank in this process. The fluid supplier 457 supplies the gaseous and liquid processing fluids to the processing chamber 412 from the storage tank 717 storing the processing fluid. Thus, the pressure in the processing space SP of the processing chamber 412 (hereinafter, referred to as a “chamber inner pressure”) and the pressure in the internal space of the storage tank 717 (hereinafter, referred to as a “tank inner pressure”) change as the process progresses.

First, the substrate conveying apparatus 3 and the supercritical processing apparatus 4 load the substrate S into the processing chamber 412 in cooperation (Step S101). Specifically, the substrate S finished with the liquid film forming process in the wet processing apparatus 2 is held by the conveyor robot 30 of the substrate conveying apparatus 3 and placed on the support tray 415 in a state pulled out from the processing chamber 412. More strictly, the substrate S is first transferred to the lift pins 437 of the supercritical processing apparatus 4 from the hand 31 of the conveyor robot 30 and, subsequently, transferred from the lift pins 437 to the support tray 415.

The support tray 415 having the substrate S placed thereon is stored into the processing chamber 412. The lid member 413 closes the aperture 421 of the processing chamber 412, whereby the processing space SP inside the processing chamber 412 is sealed. In this way, the loading of the substrate S is completed. Since the processing chamber 412 is open to an atmosphere to load the substrate S, an inner pressure of the processing chamber 412 is an atmospheric pressure Pa in an initial state as shown in an upper part of FIG. 7.

While the substrate S is transferred in this way, a predetermined standby operation is performed in the fluid supplier 457 (Step S102). Although described in detail later, the standby operation is an operation for preparing a necessary amount of the processing fluid having a temperature and a pressure suitable for use in the process later in the fluid supplier 457. As described later, in this embodiment, gaseous carbon dioxide having a temperature of 20° C. and a pressure of 6 MPa and carbon dioxide brought into the supercritical state by heating from a temperature of 20° C. and a pressure of 11 MPa are used for the process.

After the substrate S is loaded, the introduction of the processing fluid in the gas phase from the fluid supplier 457 is started (Step S103; time T1), whereby the chamber internal pressure gradually increases. If the chamber internal pressure increases to a first pressure P1 determined in advance (Step S104; time T2), the processing fluid in the supercritical state is supplied, instead of the gas, from the fluid supplier 457 to the processing chamber 412 (Step S105; time T3).

In this way, the processing space SP of the processing chamber 412 is filled with the processing fluid in the supercritical state, and the chamber internal pressure is maintained at a constant second pressure P2 larger than the first pressure P1 and a critical pressure of the processing fluid (time T4 to time T5). During that time, the liquid remaining on and adhering to the substrate S is replaced by the supercritical processing fluid and dissolved into the processing fluid, and removed from the surface of the substrate S.

If a state where the chamber internal pressure is maintained substantially at the pressure P2 passes for a predetermined time (Step S106), the discharge of the processing fluid from the processing chamber 412 is started (Step S107; time T5), whereby the processing space SP is decompressed. At and after time T7 at which the chamber internal pressure decreases to the vicinity of the atmospheric pressure Pa, the substrate S is unloaded by the conveyor robot 30 (Step S108) and the process for one substrate S is completed. If there is any substrate to be processed next (Step S109), return is made to Step S101 and the above process is repeated.

As shown in a lower part of FIG. 7, the processing fluid stored in the storage tank 717 is consumed, whereby the tank internal pressure gradually decreases. To replenish the pressurized processing fluid into the storage tank 717 to recover this, the standby operation is performed (Step S111). The standby operation can be performed at and after time T6 at which the supply of the processing fluid from the storage tank 717 to the processing chamber 412 is stopped. Therefore, as shown in FIG. 7, the standby operation can be started while the inside of the processing chamber 412 is decompressed.

In performing the supercritical drying process for the substrate S, the tank internal pressure is desirably increased to a pressure nearly equal to or slightly higher than the first pressure P1 in the standby operation so that the chamber internal pressure can be increased to the first pressure P1 in Step S103 of that process.

Specifically, the tank inner pressure is increased to the target value by causing the processing fluid output from the fluid supply source 700 to flow into the storage tank 717 while pressurizing the processing fluid by the pressure pump 715. For this purpose, the valves V71, V72 and V 74 are opened, whereas the valves V73, V75 and V76 are closed.

Thus, the processing fluid output from the fluid supply source 700 and having the pressure regulated by the valve V70 is accumulated in the storage tank 717 as a liquid pressurized to a predetermined pressure by the pressure pump 715. A liquid amount in the tank is monitored by the level sensor 718. The supply of the processing fluid is continued until the liquid having the pressure determined in advance is accumulated by an amount determined in advance. Further, the temperature of the processing fluid in the tank is regulated by the heater 719.

As just described, a process for maintaining the liquid amount, the pressure and the temperature in the tank at predetermined values is performed as the standby operation during standby periods (at and before time T1 and at and after time T6 in FIG. 7) in which the processing fluid is not supplied from the storage tank 717 to the processing chamber 412. Out of these values, the target value of the pressure is the first pressure P1 or a pressure slightly higher than the first pressure P1 and, in this embodiment, 6 MPa. Further, the target temperature is 20° C. in this embodiment. Further, the target value of the liquid amount is an amount capable of sufficiently covering the processing fluid to be supplied to the processing chamber 412 in the supercritical drying process described above.

As described above, in the first embodiment of the substrate processing apparatus according to this invention, the filters are arranged at a plurality of positions in the flow passage of the processing fluid to purify the processing fluid. The processing fluid is output as the gas, then liquefied, finally brought into the supercritical state and introduced into the processing chamber. The filters are optimized according to the state of the processing fluid at each position. In other words, each filter is arranged at the position selected from the position where the flowing processing fluid is the gas, the position where the flowing processing fluid is the liquid and the position where the flowing processing fluid is in the supercritical state in the flow passage of the processing fluid.

By doing so, the filters optimized according to the state of the processing fluid and the purpose can be arranged. As a result, the process for the substrate can be satisfactorily performed, using the effectively purified processing fluid. Further, substances easily removed in a gaseous state of the processing fluid, substances easily removed in a liquid state and substances easily removed in the supercritical state can be mixed in substances contained in the processing fluid and becoming a substrate pollution source. By arranging the filter in each flow passage of the processing fluid in each phase, these pollution substances can be effectively removed.

As described above, in the above embodiment, the supercritical processing apparatus 4 corresponds to a “substrate processing apparatus” of the invention, and the processing chamber 412 having the processing space SP serving as an “internal space” functions as a “processing chamber” of the invention. Further, the fluid supplier 457 functions as a “supplier” of the invention.

Further, in the above embodiment, the pipe groups 730, 740 and the valves arranged therein function as a “flow passage forming part” of the invention. Further, each of the heaters 725, 726 functions as a “heater” of the invention. Further, each of the filters 721, 722 corresponds to a “filter unit” of the invention, and these filters integrally constitute a “first filter”. On the other hand, each of the filters 727, 728 singly corresponds to a “second filter” of the invention. Each of the pipes 747, 748 in which these filters are arranged corresponds to a “branch passage” of the invention.

Further, in the above embodiment, the fluid supply source 700 functions as a “gas supply source” of the invention, and the refining unit 710 functions as a “liquefaction mechanism” of the invention. Further, the filter 712 functions as a “third filter” of the invention.

### SECOND EMBODIMENT

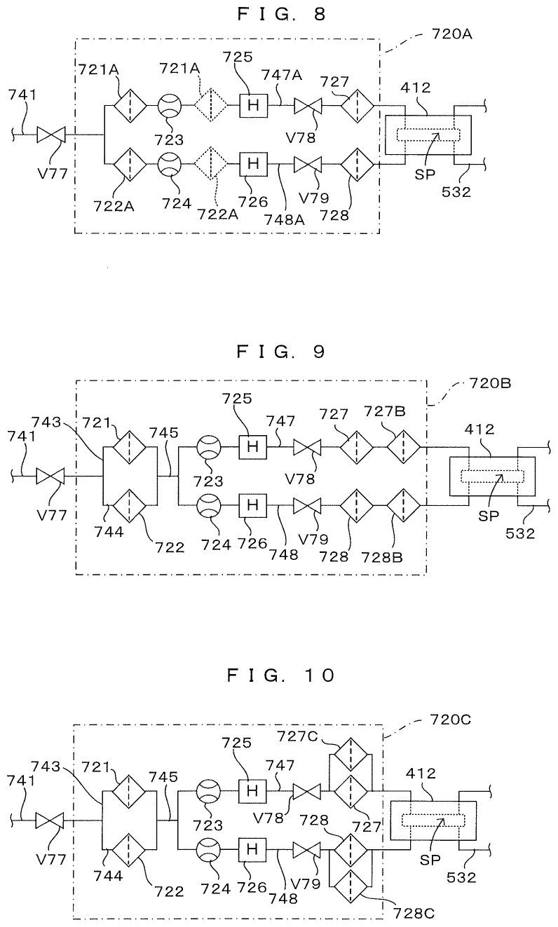

FIG. 8 is a diagram showing a second embodiment of the substrate processing apparatus. Note that, in the substrate processing apparatuses of the second embodiment and each of embodiments to be described later, the configuration of the supply unit 720 in the first embodiment is partially changed. The other components are the same as those in the first embodiment. Accordingly, to clearly specify changes from the supply unit 720, components having the same structures and functions as those of the first embodiment are not described or not described in detail by being denoted by the same reference signs.

As shown in FIG. 8, in a supply unit 720A of the second embodiment, filters 721A, 722A for liquid are provided in pipes branched from a pipe 741. That is, the pipes 743, 744 provided in the first embodiment are omitted, and two pipes 747A, 748A are directly branched from the pipe 741. The filter 721A for liquid, a flow meter 723, a heater 725, a valve V78 and a filter 727 for supercritical fluid are arranged in one pipe 747A.

Out of these, the filter 721A may be provided upstream of the flow meter 723 as shown by a solid line in FIG. 8 or may be provided downstream of the flow meter 723 as shown by a dotted line. FIG. 8 shows that the filter 721A is provided at one of these positions, but does not show that the filters 721A are provided at both positions.

Further, the filter 722A for liquid, a flow meter 724, a heater 726, a valve V79 and a filter 728 for supercritical fluid are arranged also in the other pipe 748A. Also here, the filter 722A can be positioned either in front of or behind the flow meter 723.

According to such a configuration, structures possibly becoming a pollution source can be reduced by omitting the pipes 743, 744. In this case, a flow rate of the processing fluid in each filter 721A, 722A is nearly equal to those of the filters 721, 722 connected in parallel. Thus, filter units equivalent to these can be respectively singly used.

### THIRD EMBODIMENT

FIG. 9 is a diagram showing a third embodiment of the substrate processing apparatus. 720B of this embodiment differs from the corresponding one of the first embodiment in that filters for supercritical fluid are connected in series. That is, another filter 727B is arranged upstream or downstream of a filter 727. Further, another filter 728B is arranged upstream or downstream of a filter 728. The two filters 727, 727B connected in series may have the same structure or may have different structures to be used according to a purpose. The same applies also to the other two filters 728, 728B.

Such series connection of the filters increases a pressure loss in the flow passage while being able to improve particle removal performance. Such a configuration can be also allowed in the flow passage of the supercritical fluid having a very low viscosity.

### FOURTH EMBODIMENT

FIG. 10 is a diagram showing a fourth embodiment of the substrate processing apparatus. A supply unit 720C of this embodiment differs from the corresponding one of the first embodiment in that filters for supercritical fluid are connected in parallel. That is, a filter 727C and a filter 728C are respectively connected in parallel to a filter 727 and a filter 728 arranged in a flow passage of the supercritical fluid. Such a mode is also mentioned in the description of the first embodiment. By adopting parallel connection in this way, filter units high in performance although having a small capacity can be applied. In this way, the cleanliness of the processing fluid to be introduced to a processing chamber 412 can be further enhanced.

### <Other Variations>

Note that the invention is not limited to the above embodiment, and various changes other than the aforementioned ones can be made without departing from the gist of the invention. For example, the fluid supplier 457 of the above embodiment includes many components, which are generally provided in flow passages of a processing fluid such as flow meters and filters, but not directly related to the invention. The invention can be established even if these are omitted.

Further, for example, in the above embodiment, the introduction of the processing fluid into the processing chamber 412 and the discharge of the processing fluid from the processing chamber 412 are respectively individually performed on the upper and lower sides of the support tray 415. However, this is not an essential requirement for the technical concept of the invention.

Further, since the fluid supply source 700 outputs the processing fluid in the form of the gas in the above embodiments, the filter 712 for gas is disposed in the pipe 731 serving as the flow passage of the gas. If a fluid supply source outputs a processing fluid in the form of a liquid, this filter may be changed to the one for liquid or may be omitted.

Further, in the case of providing the pipe 737 directly leading to the valve V76 from the fluid supply source 700 as shown by the dotted line in FIG. 5, a filter for gas is desirably disposed in this pipe 737.

Further, various chemical substances used in the process of the above embodiment are illustrated as some examples, and various other chemical substances can be used instead of these if those chemical substances conform to the technical concept of the invention.

As the specific embodiments have been illustrated and described above, a flow passage may be, for example, branched into a plurality of branch passages and each branch passage may be connected to a processing chamber and the heater and the second filter may be provided individually in each branch passage in a substrate processing apparatus according to the invention. According to such a configuration, a processing fluid can be supplied to the processing chamber from a plurality of points. The temperature and cleanliness of the processing fluid to be supplied can be properly maintained by arranging the heater and the second filter in each of those branch passages.

In this case, the flow passage may be, for example, branched on an output side of first filters and the first filter may be individually provided in each of the branch passages. By either configuration, the processing fluid having passed in the form of the liquid through the first filter can be supplied in the form of the supercritical fluid to the processing chamber.

Further, for example, the first filter may be configured to include a plurality of filter units having the same structure and connected in parallel to each other. The performance of a filter and the magnitude of a pressure loss are in a trade-off relationship and, particularly, the first filter handling the liquid tends to have a large pressure loss. Further, it is not easy to prepare a filter high in performance and having a large capacity. Accordingly, by connecting a plurality of filters having required performance in parallel, the capacity can be increased without lowering the performance.

Further, if the pressure loss is large, the pressure of the processing fluid decreases, whereby a temperature drop of the processing fluid caused by this possibly becomes a problem. Particularly, if a filter unit is structured to store a filter element in a housing made of metal, dew condensation caused by a temperature drop of the processing fluid causes the rusting and corrosion of the housing. By distributing the processing fluid by the parallel connection of the filters, such a temperature drop can be reduced.

Further, for example, the second filter may include filter units having the same structure as the filter unit of the first filter. The processing fluid handled by the second filter is in the supercritical state, but it cannot be said that filter units optimized for this are sufficiently available on the market. If the fluid in the supercritical state is regarded as a liquid having a very low viscosity, filter units for such a liquid can be applied. Then, filter units having the same structure as the filter units used in the first filter and handling the liquid can be utilized, whereby a cost advantage is obtained by commonly using components.

Further, in this invention, the supplier may include a gas supply source for outputting a gaseous processing fluid and a liquefaction mechanism for liquefying the processing fluid output from the gas supply source by pressurizing or cooling the processing fluid, and the liquefaction mechanism may be configured to output the liquid processing fluid to the flow passage. According to such a configuration, a process can be performed using, for example, a gas cylinder easily procurable on the market as the gas supply source. In this way, substrate processing cost can be reduced.

In this case, the gas supply source and the liquefaction mechanism are desirably connected via a third filter for filtering the gaseous processing fluid. By doing so, pollution-causing substances such as particles contained in the gas can be removed before liquefaction. Further, since a level of cleanliness required for the gas supply source can be lowered, the procurement cost of the gas supply source can be suppressed.

This invention can be applied to techniques in general for processing a substrate by a processing fluid in a supercritical state in a processing chamber.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A substrate processing apparatus for processing a substrate by a processing fluid in a supercritical state, the substrate processing apparatus comprising:
a processing chamber which has an internal space capable of storing the substrate,
a supplier which supplies the processing fluid in the form of a liquid;
a heater which heats the liquid processing fluid supplied from the fluid supplier to or above a critical temperature of the processing fluid and causing a transition into a supercritical state;
a flow passage forming part which forms a flow passage of the processing fluid from the supplier to the processing chamber by way of the heater;
a first filter which is disposed in the flow passage between the supplier and the heater and filters the liquid processing fluid; and
a second filter which is disposed in the flow passage between the heater and the processing chamber and filters the processing fluid in the supercritical state.

2. The substrate processing apparatus according to claim 1, wherein
the flow passage is branched into a plurality of branch passages and each branch passage is connected to the processing chamber, and
in each branch passage, the heater and the second filter are provided.

3. The substrate processing apparatus according to claim 2, wherein
the flow passage is branched on an output side of first filters.

4. The substrate processing apparatus according to claim 2, wherein
the first filter is individually provided in each of the branch passages.

5. The substrate processing apparatus according to claim 1, wherein
the first filter includes a plurality of filter units having a same structure and connected in parallel to each other.

6. The substrate processing apparatus according to claim 5, wherein
each of the filter unit is structured to store a filter element in a housing made of metal.

7. The substrate processing apparatus according to claim 5, wherein the second filter includes a filter unit having a same structure as the filter unit of the first filter.

8. The substrate processing apparatus according to claim 1, wherein
the supplier includes a gas supply source which outputs a gaseous processing fluid and a liquefaction mechanism which liquefies the processing fluid output from the gas supply source by pressurizing or cooling the processing fluid, and
the liquefaction mechanism outputs the liquid processing fluid to the flow passage.

9. The substrate processing apparatus according to claim 8, wherein the gas supply source and the liquefaction mechanism are connected via a third filter for filtering the gaseous processing fluid.
